(19) United States
(12) Patent Application Publication
(10) Pub. No.: US 2010/0240167 A1
(43) Pub. Date: Sep. 23, 2010

(54) Quantum confinement solar cell fabricated by atomic layer deposition

(76) Inventors: Neil Dasgupta, Menlo Park, CA (US); Wonyoung Lee, Stanford, CA (US); Timothy P. Holme, San Francisco, CA (US); Friedrich B. Prinz, Woodside, CA (US)

Correspondence Address: LUMEN PATENT FIRM, 350 Cambridge Avenue, Suite 100, PALO ALTO, CA, 94306, US

(21) Appl. No.: 12/661,778

(22) Filed: Mar. 23, 2010

Related U.S. Application Data
(60) Provisional application No. 61/210,880, filed on Mar. 23, 2009.

(51) Int. Cl. H01L 31/18; H01L 31/0352

(52) U.S. Cl. 438/63; 438/478; 977/700; 257/E31.032

(57) ABSTRACT

The current invention provides a method of fabricating quantum confinement (QC) in a solar cell that includes using atomic layer deposition (ALD) for providing at least one QC structure embedded into an intrinsic region of a p-i-n diode in the solar cell, where optical and electrical properties of the confinement structure are adjusted according to at least one dimension of the confinement structure. The QC structures can include quantum wells, quantum wires, quantum tubes, and quantum dots.

### CROSS-REFERENCE TO RELATED APPLICATIONS

This application claims priority from U.S. Provisional Patent Application 61/210,880 filed Mar. 23, 2009, which is incorporated herein by reference.

### FIELD OF THE INVENTION

The invention relates to solar cells. More specifically, the invention relates to quantum confinement solar cells and methods of fabrication, where the method takes advantage of atomic layer deposition (ALD) as a fabrication technique.

### BACKGROUND OF THE INVENTION

Several solar architectures have been proposed as replacements for single p-n junction solar cells, including multi junction cells, photoelectrochemical cells, organic-inorganic hybrid cells, and various nanostructured architectures. Among the nanostructured solar cells proposed, there is great interest in low-dimensional devices that take advantage of quantum mechanical effects. Solar cells based on quantum wells and quantum dots have been discussed as a possible route to next-generation solar cells. Specifically, the use of such quantum confinement structures would allow for the possibility of solar cells to benefit from tunable bandgaps, multiple-exciton generation (MEG) and intermediate bandgaps.

There are several challenges to the implementation of such structures. Fabrication of well-ordered quantum confinements with tight control on size requires novel techniques with control of tolerances in three-dimensions, which is difficult. Secondly, the material used as a potential barrier in the intrinsic region must be deposited conformally and pinhole-free, with desirable electronic and optical properties. Feature separation must be controlled on the angstrom scale to facilitate efficient tunneling of charge carriers. Finally, materials should be abundant and inexpensive to permit entry into the commercial photovoltaic market.

What is needed is a method of fabricating solar cells with these quantum confinement structures that results in a thin, uniform device using low-cost materials.

### SUMMARY OF THE INVENTION

The current invention is a method of fabricating quantum confinement (QC) in a solar cell that includes using atomic layer deposition (ALD) for providing at least one QC structure embedded in an intrinsic region of a p-i-n diode in the solar cell, where optical and electrical properties of the confinement structure are adjusted according to at least one dimension of the confinement structure.

According to one aspect of the invention, the QC structure can be a quantum dot, a quantum well, a quantum wire, or a quantum tube. The quantum dots are fabricated using nucleation limited growth to provide island formation of the QC structures, using nanopatterning from lithographic resist materials, or using nanopatterning from self-assembled monolayers. The quantum wells can be fabricated by depositing thin films of a semiconducting material by ALD, wherein the films are deposited in a layered structure between a secondary material having a higher bandgap than the quantum well layer. The quantum wires can be fabricated by ALD using a templated growth mechanism including deposition into a nanoporous material.

In another aspect of the invention, depositing the QC structure in the intrinsic region of the p-i-n diode includes providing a precursor molecule that contains at least one material of the QC structure to an ALD chamber.

In one aspect of the invention, depositing the QC structure in the intrinsic region of the p-i-n diode includes using a remote plasma source as a precursor.

According to another aspect of the invention, depositing the QC structure in the intrinsic region of the p-i-n diode includes using post-annealing of ALD films or phase segregation of supersaturated materials.

In one aspect of the invention, fabrication of the QC structure comprises using material having a bandgap in a range of 0.0 eV to 1.5 eV, where when the material experiences the QC structure state, the bandgap increases to a bandgap useful for the solar cell.

In yet another aspect of the invention, fabrication of the QC structure includes using a material having a Bohr exciton radius in a range of 1 nm to 100 nm, and the material includes an effective mass of one of the charge carriers in a range of 0.01*m₀ to 0.9*m₀.

According to one aspect of the invention, the QC structures include low-bandgap materials having bandgaps in a range of 0.0 eV to 1.5 eV.

In another aspect of the invention, the solar cell includes a bottom electrode, a p-barrier, the intrinsic region, an n-barrier and a top electrode, where at least one QC structure is disposed in the intrinsic region. Here, the p-barrier or the n-barrier can include high-bandgap materials having bandgaps in a range of 1.0 eV to 4.0 eV.

In another aspect of the invention, the solar cell includes at least two QC layers of different Fermi levels disposed in the intrinsic layer, wherein the different Fermi levels are according to different size, different shape, or different material.

In a further aspect of the invention, the intrinsic region is a dielectric material.

In another aspect of the invention, the solar cell includes bulk heterojunction architectures, where the heterojunction includes an n-type material and a p-type material.

According to one aspect of the invention, the p-i-n diode includes a substrate, wherein the substrate includes a first diode material having at least one vertical feature, where the intrinsic region having at least one embedded QC structure is disposed on a surface of the at least one vertical feature, where a second diode layer is disposed on the intrinsic region, where an excited carrier diffusion length from the second diode material to the first diode material is decoupled from an absorption length of the solar cell. In this aspect, the first diode material includes an n-type semiconductor material or a p-type semiconductor material, and the second diode material includes a p-type semiconductor material or an n-type semiconductor material. Further, the vertical feature is a cone or a to pillar, where the vertical feature has a diameter in a range of 1 nm to 100 μm. Here, the n-type material includes a semiconductor material having a bandgap in a range of 1.0 eV to 4.0 eV, and the p-type material includes a semiconductor material having a bandgap in a range of 1.0 eV to 4.0 eV. Additionally, the vertical feature may be formed using nanosphere lithography, reactive ion etching, stamping or photolithography.

### BRIEF DESCRIPTION OF THE DRAWINGS

FIGS. 1a-1c show schematic planar views of exemplary QC solar cells fabricated by atomic layer deposition which incorporate QC structures into a solar cell according to the present invention.

FIGS. 2a-2c show schematic planar views of some exemplary 3-D QC structured solar cell architectures according to the present invention.

FIGS. 3a-3b show examples of Si nanopillars according to the present invention.

FIG. 4 shows an SEM image of a CuSCN film deposited into the pores of a nanorod template according to the present invention.

### DETAILED DESCRIPTION

Quantum confinement (QC) structures such as quantum wells, quantum wires, quantum tubes and quantum dots possess several attractive characteristics that can benefit solar cell performance. Due to quantum mechanical effects on confined charge carriers, the bandgap of such structures can be tuned by controlling the confinement dimension. Additionally, the ability to produce multiple excited charge carriers from a single high-energy photon is exhibited in QCs, according to the current invention. This aspect allows a solar cell benefiting from QC structures to avoid the Shockley-Quaissar limit. Furthermore, mini-band structures formed by superlattices of QCs allow for efficient charge transport through a device.

The current invention uses atomic layer deposition (ALD) to fabricate QC structures. ALD is a thin-film fabrication technique based on a modified metalorganic chemical vapor deposition (MOCVD) process, where precursor chemicals are introduced sequentially into a reaction chamber in order to build up a maximum of one atomic layer per cycle. Unlike MOCVD, where precursor molecules are decomposed at high temperatures and growth is determined by reaction time, in ALD the film growth saturates after each precursor pulse, so that the growth rate is completely determined by the number of cycles used in the growth. Films can ideally be grown pinhole-free with sub-nm precision in thickness.

The QC solar cell fabricated by atomic layer deposition incorporates QC structures into a solar cell, where the QC structures include quantum wells, quantum wires, quantum tubes or quantum dots. These structures are embedded in the intrinsic region of a p-i-n diode, in order to facilitate charge extraction. In one embodiment, the substrate for deposition is a metallic back electrode. The top electrode is either a transparent conducting electrode, or a patterned or random grid of conducting material.

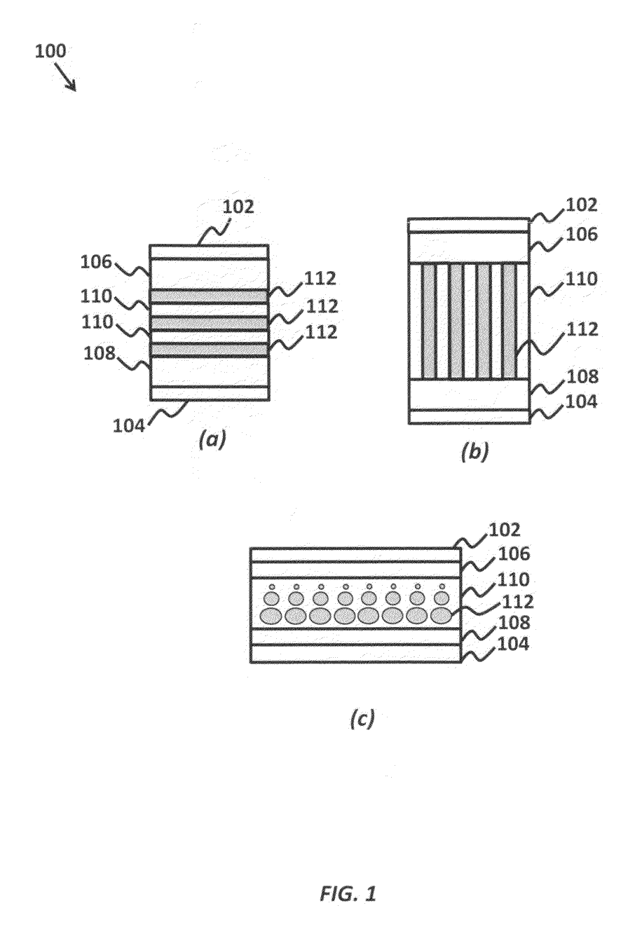

FIGS. 1a-1c show schematic planar views of exemplary QC solar cells 100 fabricated by atomic layer deposition which incorporate QC structures into a solar cell according to the present invention. FIGS. 1a-1c show a solar cell 100 that includes a top electrode 102, a bottom electrode 104, an n-type material 106, a p-type material 108 and an intrinsic region barrier material 110 disposed between the n-type material 106 and the p-type material 108 to form a p-i-n diode, where QC structures 112 are embedded in the intrinsic region barrier material 110. FIG. 1a shows one embodiment of the solar cell 100, where the intrinsic region barrier material 110 is embedded with quantum well QC structures 112. FIG. 1b shows another embodiment of the solar cell 100, where the intrinsic region barrier material 110 is embedded with quantum wire or quantum tube QC structures 112.

FIG. 1c shows a further embodiment of the solar cell 100, where the intrinsic region barrier material 110 is embedded with quantum dot QC structures 112. In the above embodiments, in a generic context the p-i-n diode can include an intrinsic region barrier material [A] disposed between a p-type material [A] and an n-type material [A], with the QC structures imbedded in the intrinsic region barrier material [A]. For example the intrinsic region barrier material can be ZnS disposed between a p-type ZnS and an n-type ZnS with PbS QC structures embedded in the intrinsic region barrier material ZnS, where the QC structures can include quantum dots, quantum wires, quantum tubes or quantum wells.

ALD provides several advantages over other techniques for fabrication of a quantum confinement solar cell 100. The precise control of film thickness with sub-nm precision allows for much easier control of feature dimensions, which can be critical for bandgap engineering of QC structures 112. ALD also allows a wide variety of compound and elemental materials to be deposited. A unique and important aspect of ALD over other deposition techniques is the ability to deposit highly conformal films on high aspect ratio structures. This is important both for fabrication of QC structures 112 into templates with narrow pores, and for uniform coating of 3-D QC structures 112 with the intrinsic region barrier material 110. Finally, the low vacuum and temperature conditions of ALD allow for integration into fabrication processes that are not compatible with typical CVD or MBE reactors which require higher temperatures and/or vacuum levels.

The quantum well QC structures 112 can be fabricated by depositing thin films of a semiconducting material by ALD, typically with thicknesses below 20 nm. These films are deposited in a sandwich structure between a secondary material with a higher bandgap. The quantum wire QC structures 112 are fabricated by ALD using a templated growth mechanism such as deposition into a nanoporous material. Examples of template materials include anodized aluminum oxide (AAO) or track-etched polycarbonate membranes. The quantum dot QC structures 112 are fabricated by ALD using various methods, including nucleation limited growth, which leads to island formation, post-annealing of ALD films, phase segregation of supersaturated materials nanopatterning of lithographic resist materials, or nanopatterning of self-assembled monolayers (SAMs). These QC structures 112 are placed in the intrinsic region barrier material 110 of a p-i-n diode, which is also fabricated by ALD.

Doping of the p-i-n diode material is achieved by ALD by various methods. One method is the direct incorporation of dopant elements into the film by choosing a precursor molecule that contains the dopant atom. This precursor is pulsed once for every several normal ALD cycles of the intrinsic material 110 to control the concentration of the dopant atom in the film. An alternate method of incorporating dopant atoms into the p-i-n diode is by using a remote plasma source as a precursor. Finally, dopant atoms may be incorporated after fabrication of the structure, by methods such as ion implantation or diffusion doping.

In order to effectively absorb incident light and convert the light energy into electronic energy, a highly-absorbing semiconductor material is chosen to fabricate the QC structures 112. A low-bandgap semiconductor having a bandgap in a range of 0.0 eV to 1.5 eV is used, so that when it experiences quantum confinement, the bandgap increases to an appropriate value for solar cells 100. Additionally, a material is used with a large Bohr exciton in a range of 1 nm to 100 nm, and one charge carrier effective mass of one of the charge carriers in a range of 0.01*m₀ to 0.9*m₀ in order to facilitate strong confinement effects over a wide range of feature sizes in a range of 1 nm to 100 nm. Finally, a material is used that exhibits multiple exciton generation in the case of the quantum dot solar cell 100.

The purpose of the intrinsic region barrier material 110 in the quantum confinement solar cell 100 is multi-fold. First, it is used to confine electrons in the absorbing material, so it requires a significantly larger band gap than the QC structure. However, it also serves as the barrier to quantum mechanical tunneling, which is required to extract current in the device. Since tunneling current will decrease with increasing barrier height, if a material with a very wide bandgap is chosen, tunneling probability will be undesirably low.

Another important characteristic of the intrinsic region barrier material 110 is the dielectric constant. Since the charge separation in the solar cell is facilitated by the internal electric field provided by the p-i-n diode, a material with a low dielectric constant is used to avoid shielding this internal field. The intrinsic region barrier material 110 has similar chemical and crystallographic properties as the absorbing material, to minimize formation of misfit dislocations and interdiffusion between layers.

According to one aspect of the invention, the QC structures include low-bandgap materials having bandgaps in a range of 0.0 eV to 1.5 eV.

In another aspect of the invention, the solar cell includes a bottom electrode, a p-barrier, the intrinsic region, an n-barrier and a top electrode, where at least one QC structure is disposed in the intrinsic region. According to the invention, the p-barrier can include high-bandgap materials having bandgaps in a range of 1.0 eV to 4.0 eV. Further the n-barrier can include high-bandgap materials having bandgaps in a range of 1.0 eV to 4.0 eV. The intrinsic region material need not be the same as either the p-type or the n-type material, however the intrinsic region material can have bandgaps in a range of 1.0 eV to 4.0 eV.

A list of useful materials for the QC structures 112 includes low-bandgap materials such as PbS, PbSe, PbTe, InAs, CdS, CdSe, CuInS₂, CuInSe₂, InP, SnO₂, MnO₂, or HgTe, and a list useful intrinsic region barrier materials 110 includes ZnS, ZnO, SnO₂, GaN, CdS, CdSe, In₂S₃, Fe₂S₃, Bi₂S₃, SiO₂, HfO₂, or ZrO₂. These materials are able to be deposited by ALD, and match the selection criteria outlined above. Additionally the n-type material 106 or the p-type material 108 can include ZnS, ZnO, SnO₂, GaN, CdS, CdSe, In2S₃, Fe₂S₃, Bi₂S₃, SiO₂, TiO₂, Si, GaAs, Ge, ZrO₂, CuSCN, CuAlO₂, CuI or semiconducting polymers.

In another aspect of the invention, the solar cell includes at least two QC layers of different Fermi levels disposed in the intrinsic layer, wherein the different Fermi levels are according to different size, different shape, or different material, or any combination thereof.

According to one aspect, the invention uses heterojunctions involving different n-type and p-type materials, as utilized in a variety of thin-film solar cells, including CIGS and TiO₂ based bulk heterojunction architectures. It is desirable to develop ultra-thin architectures to minimize the diffusion length required of carriers, as an increasing number of barrier layers will decrease the probability of charge carriers diffusing to the electrodes before recombining. The current invention includes a method of fabricating 3-D nanostructured architectures, which take advantage of the benefits of ALD as a highly-conformal deposition technique, while maintaining the requirements of a high-efficiency solar cell.

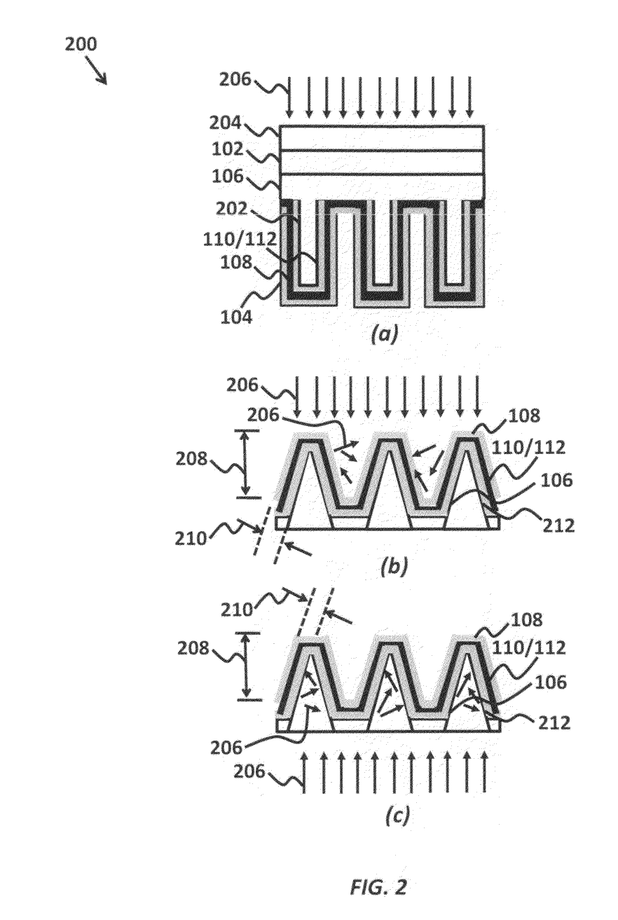

FIGS. 2a-2c show schematic planar views of some exemplary 3-D QC structured solar cell architectures 200. FIG. 2a shows a 3-D architecture based on a columnar of nanorods/nanowires or nanotubes 202 made from an n-type material 106, such as ZnO or TiO₂ for example. These columnar nanostructures 202 are coated with an absorbing layer of the QC structures 112 embedded in the intrinsic material 110, for example, QC structures 112 based on PbS—ZnS super-lattice structures. A p-type material 108, such as CuAlO₂ for example, is provided to fill in the pores, and complete the diode fabrication. A bottom conductor 104 layer is disposed on the p-type material later 108 to provide a conductive and reflective coating as the outer layer. A top conductor layer 102, such as AZO, for example, is disposed on the n-type material 106, and a glass layer 204 is disposed on the top conductor 102 as an outer layer for the 3-D QC structured solar cell 200. Light 206 is shown illuminating the 3-D QC structured solar cell 200 from the top. The p-type material may be disposed on the top or on the bottom of the 3-D QC structured solar cell 200.

The embodiments in FIGS. 2b-2c show a 3-D QC structured solar cell 200 that decouples the absorption length 208 from the diffusion length 210 of the active device, where shown is a cone-shaped substrate 212, such as glass or quartz, having nano-size cones for providing a substrate material to deposit the p-i-n diode using the ALD process, where the conductor and glass layers have been omitted for illustrative purposes. In these examples, the nano-cones 212 are coated with an n-type material 106, and an absorbing layer of the QC structures 112 embedded in the intrinsic material 110 is deposited there on. The p-type material layer 108 is deposited on the intrinsic layer with the embedded QC structures 110/112. A comparison of FIG. 2a to FIG. 2b shows that the nanocone structure 212 can be used to gather light 206 from either the top or bottom side of the nanocone structures 210.

The structures of the embodiments shown in FIGS. 2a-2c solve a variety of challenges for quantum confinement solar cells fabricated by ALD. First, the total deposited thickness can be very thin, which greatly reduces the number of required ALD cycles, and therefore the required manufacturing time. Furthermore, a shorter device thickness allows much more efficient charge extraction than a device in which carriers have to tunnel through several barriers. Further, the volume of space occupied by the absorber layer is greatly enhanced due to the 3-D architecture, allowing for sufficient light absorption.

To further enhance the absorption of light, varying the vertical profile of the nanorod sidewalls can provide additional absorption of the light. Using a more conical form, light can be effectively scattered (see FIGS. 2b-2c) and absorbed in a thin film device, and reflection losses can be greatly reduced when the feature size is on the order of the wavelength of light. According to one aspect of the invention, the vertical structure templates for deposition of solar cells can have a diameter in a range of 1 nm to 100 μm.

In another aspect, the n-type material includes a semiconductor material having a bandgap in a range of 1.0 eV to 4.0 eV, and the p-type material includes a semiconductor material having a bandgap in a range of 1.0 eV to 4.0 eV. Additionally, the vertical structure is formed using nanosphere lithography, reactive ion etching, stamping or photolithography.

In order to achieve the nanostructured template, a combination of nanosphere lithography and reactive ion etching can be used for etching nanopillars into a substrate, such as Si or a transparent material such as glass, for example, as a mold. An example of Si nanopillars 300 fabricated using spin-cast latex microspheres is shown in FIGS. 3a-3b, where the silicon nanorods were fabricated by reactive ion etching of a latex nanosphere mask with a diameter of 120 nm, as shown in FIG. 3a and a diameter of 5 μm, as shown in FIG. 3b. The sidewall profile can be controlled to provide a cylindrical or a conical geometry of the pillars. The nanostructured template may also be created by stamping or photolithography.

According to one aspect, the invention includes etching nanorods into transparent substrates such as glass or quartz wafers, as the architecture shown in FIG. 3b. Latex microspheres can be used as the initial masking material or Langmuir-Blodgett films of SiO₂ spheres. This nanostructured quartz template serves as the substrate for subsequent solar cell fabrication.

In one aspect, the invention uses a quartz substrate due to its transparency and compatibility with CMOS processing. The method includes using nanosphere lithography (NSL) combined with reactive ion etching (RIE) to create nanocones on the surface of a quartz substrate, where the quartz is etched using standard etching recipes for SiO₂. In on example, 500 nm nanospheres are used, as this corresponds to roughly the middle of the range of visible wavelengths of light. Therefore, visible light will be scattered effectively by a periodic array with this spacing. The particles are obtained in a suspension, with 0.1-10% polystyrene and 90-99.9% water. The nanospheres are spincast onto silicon and quartz substrates in order to optimize the formation of a close-packed monolayer of nanospheres. The rotational speed of the substrate during spin-casting is a key parameter in formation of a close-packed layer, for example a rotational speed of 2000 rpm is useful for obtaining a closed packed monolayer of spheres formed on the surface, with some defects such as vacancies and double layers.

Once the spincasting procedure is complete, the latex nanospheres are used as a mask for RIE of quartz substrates. The first etching step is an oxygen-based plasma, which is used to downsize the diameter of the particles before etching the quartz. This creates a gap between the particles, which defines the spacing between nanorods/nanocones after etching the quartz. By controlling the time of this downsizing etch, the size of the gap between nanorods can be precisely controlled. An etch time of 2 minutes is used for this example. For quartz etching, fluorine based etches are used, including combinations of NF₃, CHF₃ and O₂ plasmas.

Using a higher ratio of oxygen to Freon results in a more cone like shape, as well as further spacing between the nanocones. This is due to the fact that the oxygen plasma etches the latex nanospheres during the quartz etching, effectively downsizing the particles as a function of time during the etching. This in turn exposes more area between spheres causing a larger gap between nanorods, as well as a conical shape due to the reduction of mask size as a function of etch time. By controlling etch parameters such as gas flow rates, the shape of the nanostructured template is accurately controlled.

In another aspect of the invention, heterojunctions based on different p-type and n-type materials are used. There are several advantages to this for solar cells. First, by using materials that naturally form a diode without doping, it greatly simplifies the purity requirements of the cell. Secondly, there are several heterojunctions that are based on ZnO as the n-type layer, which fits well with the use of AZO as the transparent conductive oxide. It also allows selection of a barrier material for the quantum confinement region that is independent of its dopant characteristics.

While reasonably good pore filling characteristics have been observed with the solution-based deposition of CuSCN, the current invention uses ALD for conformal deposition of inorganic films into high aspect ratio structures. By depositing the p-type material using ALD, the entire active solar cell device may be fabricated in a single ALD chamber, where deposition of p-type materials, which form a type II heterojunction with ZnO is provided. CuAlO₂ has been is an effective p-type material for solar cells. This material has a relatively simple chemical composition, with available precursors for Cu as well as Al.

In another aspect of the invention, other p-type materials are used to form a heterojunction diode that include CuSCN and CuAlO₂. According to the invention, the method for deposition of CuSCN is based on a liquid injection technique where a solution of CuSCN dissolved in propyl sulfide is deposited uniformly on a substrate using a syringe pump and needle. The substrate is maintained at a temperature of approximately 100° C. This causes evaporation of the propyl sulfide, and solidification of a CuSCN film. This technique provides diode behavior in several material systems for extremely thin absorber (ETA) solar cells. The current invention uses a deposition system for liquid injection of CuSCN.

According to one aspect of the invention, to deposit a CuSCN film, a solution is prepared by stirring powder CuSCN in propylsulfide (PS) for 12 h. A mixture of 0.07 g of CuSCN in 10 mL of PS is used to make a 0.06 M solution. This concentration enables successful deposition of transparent CuSCN films. In this example, the solution was left to settle for two days before use.

In one exemplary embodiment, depositing CuSCN includes a syringe pump, hot plate, perforated needle, and motorized stage. These components enable a systematic method of film deposition. The syringe pump is responsible for controlling the flow rate of the CuSCN solution, which is then distributed evenly along the width of the substrate by the needle. A customized needle is provided, with ˜0.3 mm holes drilled onto the sidewall of the tubing, spread out over a total distance of 1.5 cm. The end of the needles is closed, causing a showerhead-type flow of liquid, which spreads evenly over the surface of the substrate. During deposition, the hot plate provides rapid evaporation of PS in the deposited solution. The hot plate is kept at 100° C. By programming the motorized stage to have a constant velocity and traveling distance, the solution is evenly distributed along the length of the substrate.

Once the solution is ready, the syringe pump is equipped with 1 mL of the mixture. An initial flow rate of 100 μL/min is used to load the system with the solution. During deposition, the flow rate is reduced to 10 μL/min. The perforated needle is 0.5 to 1 mm above the pre-heated substrate. A program script is coded and tested before every run. The code specifies the needle's spreading speed (1.5 mm/sec) and traveling distance (15 cm). The number of applications is defined by looping the movement of the needle, where one loop includes two applications.

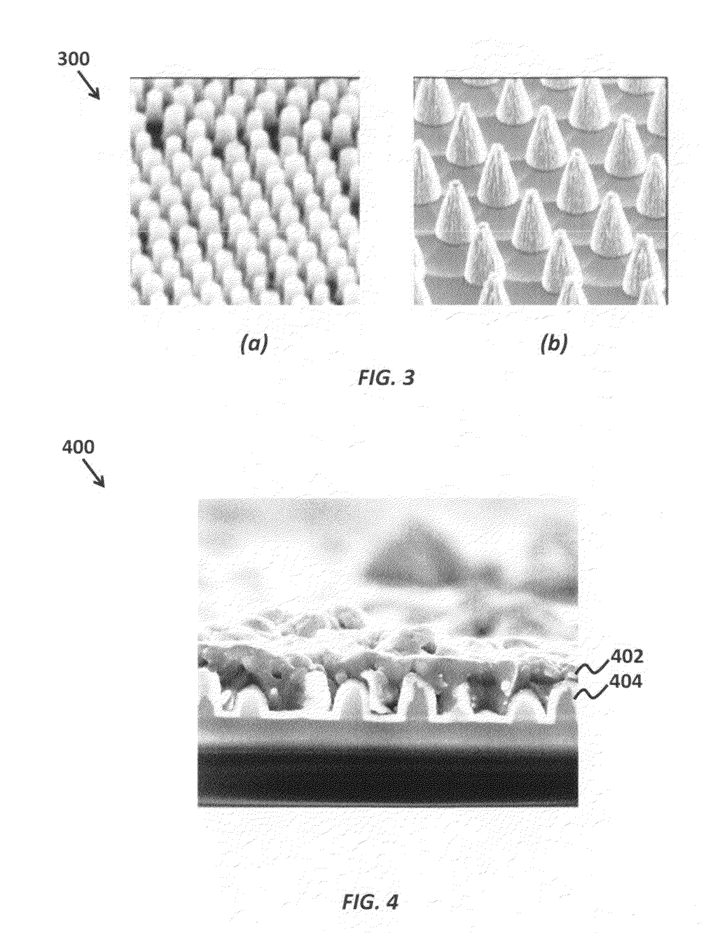

The CuSCN films have been deposited on various surfaces. The thickness and uniformity of the film heavily depends on the substrate's topography. The substrate's surface roughness is important because it determined the film's adhesion. A textured surface provides crevices. Such crevices are filled with CuSCN that served as nucleation sites. Evenly distributed nucleation sites result in a uniform layer of CuSCN. The nanopillars provide an excellent distribution of nucleation sites for the solution deposition. If the empty space between the nanopillars is significant, more passes are required to form a thicker and uniform layer. In one example, the passes results in a ˜0.5 μm thick CuSCN film that caps the nanopillars. FIG. 4 shows an SEM image 400 of CuSCN film 402 deposited into the pores of a nanorod template 404, which was coated by ˜90 nm of ALD AZO. Here, it can be seen that few pinholes, if any, exist.

In a further aspect, thin invention includes fabrication of copper aluminum dioxide by ALD. CuAlO₂ is an effective p-type material for pn-junctions when paired with ZnO. Deposition of CuAlO₂ using ALD is critical because it allows the deposition of a conformal layer of the material on top of the nanocone or nanopillar anti-reflective solar cell structure. An additional benefit of CuAlO₂ is its relative transparency which is optimally on the order of 50% to 60% in bulk but much higher for a thin film with a suitable deposition process. Thus, it can be used in the fabrication of stacked multi-junction solar cells.

The successful deposition CuO and CuO₂ by the inventors using various precursors such as Cu tetramethyl heptanodionate, Cu hexafluoroacetylacetonate and Bis(N,N′-di-sec-butylacetamidinato)dicopper, enables the matching of the correct stoichiometry of CuAlO₂ by alternate ALD cycles of Al₂O₃ and CuO/CuO₂. Copper aluminum dioxide has a delafossite structure so that to achieve stoichiometric growth, repeating layers of Cu—O—Al—O are accomplished when the proper precursor chemistry is used. Alternatively, CuAlO₂ could be deposited by other standard thin-film fabrication techniques, including sputtering, chemical vapor deposition, or pulsed laser deposition.

The present invention has now been described in accordance with several exemplary embodiments, which are intended to be illustrative in all aspects, rather than restrictive. Thus, the present invention is capable of many variations in detailed implementation, which may be derived from the description contained herein by a person of ordinary skill in the art. All such variations are considered to be within the scope and spirit of the present invention as defined by the following claims and their legal equivalents.

What is claimed:

1. A method of providing quantum confinement (QC) in a solar cell comprising using atomic layer deposition (ALD) for providing at least one QC structure embedded in an intrinsic region of a p-i-n diode in said solar cell, wherein optical and electrical properties of said confinement structure are adjusted according to at least one dimension of said confinement structure.

2. The method of claim 1, wherein said QC structure is selected from the group consisting of a quantum dot, a quantum well, a quantum wire, and a quantum tube.

3. The method of claim 2, wherein said quantum dots are fabricated using nucleation limited growth to provide island formation of said QC structures, using nanopatterning from lithographic resist materials, or using nanopatterning from self-assembled monolayers.

4. The method of claim 2, wherein said quantum wells are fabricated by depositing thin films of a semiconducting material by said ALD, wherein said films are deposited in a layered structure between a secondary material having a higher bandgap than said quantum well layer.

5. The method of claim 2, wherein said quantum wires are fabricated by said ALD using a templated growth mechanism comprising deposition into a nanoporous material.

6. The method of claim 1, wherein said depositing said QC structure into said intrinsic region of said p-i-n diode comprises providing a precursor molecule that contains at least one material having said QC structure to an ALD chamber.

7. The method of claim 1, wherein said depositing said QC structure into said intrinsic region of said p-i-n diode comprises using a remote plasma source as a precursor.

8. The method of claim 1, wherein said depositing said QC structure into said intrinsic region of said p-i-n diode comprises using, post-annealing of ALD films or phase segregation of supersaturated materials.

9. The method of claim 1, wherein fabrication of said QC structure comprises material having a bandgap in a range of 0.0 eV to 1.5 eV, wherein when said material experiences said QC structure state, said bandgap increases to a bandgap useful for said solar cell.

10. The method of claim 1, wherein fabrication of said QC structure comprises using a material having a Bohr exciton radius in a range of 1 nm to 100 nm, and said material comprises an effective mass in a range of 0.01*m₀ to 0.9*m₀.

11. The method of claim 1, wherein said QC structures comprise low-bandgap materials having bandgaps in a range of 0.0 eV to 1.5 eV.

12. The method of claim 1, wherein said solar cell comprises a bottom electrode, a p-barrier, said intrinsic region, an n-barrier and a top electrode, wherein at least one said QC structure is disposed in said intrinsic region.

13. The method of claim 12, wherein said p-barrier or said n-barrier comprises a high-bandgap material having a bandgap in a range of 1.0 eV to 4.0 eV.

14. The method of claim 1, wherein said solar cell comprises at least two QC layers of different Fermi levels disposed in said intrinsic layer, wherein said different Fermi levels arise according to i) a different size, ii) a different shape, iii) a different material, i) and ii), i) and iii), ii) and iii), or i) and ii) and iii).

15. The method of claim 1, wherein said intrinsic region comprises a dielectric material.

16. The method of claim 1, wherein said solar cell comprises bulk heterojunction architectures, wherein said heterojunction comprises an n-type material and a p-type material.

17. The method of claim 1, wherein said p-i-n diode comprises a substrate, wherein said substrate comprises a first diode material having at least one vertical feature, wherein said intrinsic region having at least one said embedded QC structure is disposed on a surface of said at least one vertical feature, wherein a second diode layer is disposed on said intrinsic region, wherein a diffusion length from said second diode material to said first diode material is decoupled from an absorption length of said solar cell.

18. The method of claim 17, wherein said first diode material comprises an n-type semiconductor material or a p-type semiconductor material, and said second diode material comprises a p-type semiconductor material or an n-type semiconductor material.

19. The method of claim 17, wherein said vertical feature is a cone or a pillar, wherein said vertical feature has a diameter in a range of 1 nm to 100 μm.

20. The method of claim 17, wherein said n-type material comprises a semiconductor material having a bandgap in a range of 1.0 eV to 4.0 eV.

21. The method of claim 17, wherein said p-type material comprises a semiconductor material having a bandgap in a range of 1.0 eV to 4.0 eV.

22. The method of claim 17, wherein said vertical feature is formed using nanosphere lithography, reactive ion etching, stamping or photolithography.
